(19) United States
(12) Patent Application Publication
(10) Pub. No.: US 2004/0137664 A1
(43) Pub. Date: Jul. 15, 2004

(54) Advanced packaging shell for pocketable consumer electronic devices

(76) Inventors: Gidon Elazar, Tzur Igal (IL); Dan Harkabi, Moshav Lachish (IL); Nehemiah Weingarten, Tel-Aviv (IL); Claudio Franco, Montebelluna (Treviso) (IT)

Correspondence Address: Nehemiah Weingarten (MDRM), c/o Yael Hilerowitz-Gur at FAHN KANEH CONSULT., Migdal Levinshtain 13th floor, 23 Petach-Tikva Road, Tel-Aviv, 66184, IL

(21) Appl. No.: 10/751,977

(22) Filed: Jan. 7, 2004

Related U.S. Application Data
(60) Provisional application No. 60/438,580, filed on Jan. 9, 2003.

(51) Int. Cl. H01L 21/44

(52) U.S. Cl. 438/127

(57) ABSTRACT

A method for encapsulating electronic components in consumer electronic devices is disclosed. A sealed packaging shell for electronic components is created from a single monolithic piece of elastomeric material. Electronic components, including a PCB, are hermetically encapsulated within the packaging shell during the process of its formation.

### RELATED U.S. APPLICATION

This application claims the benefit of provisional patent applications serial No. 60/438,580, filed Jan. 9, 2003.

### FIELD OF THE INVENTION

This invention generally relates to consumer electronics. More particularly this invention relates to processes and materials used to shell pocketable consumer electronics devices.

### BACKGROUND OF THE INVENTION

Advances in electronic device miniaturization in the last decade have brought about a new category of pocketable consumer electronic devices, which are used as personal articles. Examples of such devices are USB flash storage devices, remote control car alarms, cellular phones, PDAs, MP3 players and the like. These devices are carried in a users pocket or pocketbook, and their physical proximity to the user provides a sense of ownership, personality and perhaps a fashion statement.

Consumer electronic devices are generally made up of an internal electronic assembly and an external casing used to house the electronics and provide a commercially acceptable aesthetic appearance. The internals are typically built onto one or more printed circuit board (PCB). The external packaging shell is in many cases made of plastic materials, such as Acrylonitrile Butadiene Styrene Copolymer (ABS), Polycarbonate (PC) or the like. Such materials are relatively easy to manipulate in order to provide an appealing appearance and their production cost is low in very large quantities.

Plastic shells are usually manufactured by mixing several chemical substances into a culture and injecting the culture into molds. The molding process usually involves very high temperatures and pressures. The molds used for creating plastic shells are built to withstand these high pressures and temperatures. As a result, the materials and tooling process of creating such molds are relatively expensive. Therefore, once a mold has been made, there is an economy of scale for using it as much as possible to create many identical plastic shells.

Some types of epoxy cultures don't require high temperatures and pressures in the mold, thus enabling a cheaper tooling of the mold. The shortcoming of epoxies though, is the need for long hardening time of the shell. This limits the number of shells that can be produced in mass production in a certain amount of time.

The nature of pocketable consumer electronic devices drives specific product requirements, due to environmental conditions, manufacturing and/or market considerations. For example, in order to push device-manufacturing cost as low as possible, the shell is usually composed of as few parts as possible, as manufacturing cost is related to the number of parts of the plastic shell. Unfortunately, shells built from plastic materials usually require two or more plastic parts in order to adequately and fully encapsulate the internal electronics. This is due to the nature of the assembly process and plastic molding tools.

Ideally, the plastic shell would be produced directly onto the consumer electronic device skeleton. Unfortunately, existing art cannot enable this because of the high temperature and pressure inside a mold that would cause severe damage to the electronic circuitry of the device. Therfore, in these assembly processes, the plastic shell components are first produced and only later are assembled together with the electronic components to create the consumer electronic device.

If the consumer electronic device includes light emitting components, such as Light Emitting Diodes (LEDs), additional transparent or translucent light conductive plastic parts might be required to conduct the light out of the shell, adding to the overall cost of the device manufacturing.

Furthermore in order to best fit the users' pocket or key fob, the device must be made as small as possible. Unfortunately, when using plastic as the packaging shell, a minimum of width of the plastic is needed to strengthen the shell, and a minimum clearance space between the electronics and the shell is required. These requirements drive to enlarge the overall dimensions of the device.

Due to the characteristics of the user's pocket or pocketbook environment, a personal electronic device must be made durable enough, both in operating or non-operating mode, to sustain an environment which includes dirt, dust, humidity, and other particles which may harm the internal electronics, inhibit the proper operation of the device, and even render the device useless. Furthermore the device must stand contact and friction with other objects found in the pocket or pocketbook, such as metal door or car keys, or withstand a fall, which may harm the plastic shell or even break it. Furthermore, the device should remain operational after immersion in water, for example hot water and detergents when accidentally thrown into a washing machine while remaining in a pants pocket, and the like challenges. Unfortunately, low cost plastic shells are not hermetically sealed and may allow dust, particles and water into the device. Shells based on plastics may be sealed and strengthened using additional materials and components, such as rubber or silicon seals, but this process adds components and labor and increases the device manufacture cost.

In various scenarios, the markets demand customization and/or personalization of pocketable consumer electronic devices. For example, a device manufacturer sells devices through an OEM (Original Equipment Manufacturer) channel to various client companies. Each client company may require its own customization and personality imprinted on the device. For example Nokia sells cellular phones to the European cellular operator Orange and imprints the Orange logo onto its products. Plastic shells enable an easy customization of device shell color or the imprint of a logo on the shell design. This process can be economic even for relatively small quantities of devices. Unfortunately though, plastic shells don't allow easily and economically changing the shell's physical shape as part of the customization, due to the high tooling costs when using plastic molds. Producing a new plastic mold for a low quantity production is not an economic process.

A possible marketing advantage of pocketable consumer devices is to be able to differentiate one particular device from another. This differentiation may enable end users to distinguish their own device from other devices and enhance the ownership and personal experience. Unfortunately, plastic injection by nature does not allow differentiation between each particular device as part of the plastic injection process. Once set up to inject a batch of molds, all resulting plastic shells are essentially identical. In order to create differentiation for particular devices, additional components must be added, increasing the overall production cost.

There is clearly an unmet need for packaging shell materials and method that overcome the above mentioned problems and provide solutions for the specific requirements of shells for pocketable consumer electronic devices.

### SUMMARY OF THE INVENTION

The present invention provides a solution to the problems stated above and describes a method to produce a shell for consumer electronic devices in a process that enables one or more of the following enhancements: lower production cost, faster production time, reduced product dimensions, increased mechanical durability, improved environmental characteristics such as water resistance and the like, economic production of new shell designs for relatively small quantities, differentiation between each particular device.

According to the present invention, elastomeric materials, for example polyurethane or the like, which are formed through a chemical reaction between two or more substances, are used to form the shell of the pocketable consumer electronic device. The chemical reaction takes place in the presence of the electronics of the device. This process creates a monolithic shell, hermetically encapsulating the electronics inside, commercially acceptable, aesthetic, and environmentally durable on the outside. According to the present invention, the temperature and pressure ranges required to create the shell are substantially lower than the typical temperature and pressure used within a plastic mold, therefore the electronics of the device survive that process. Moreover, the mold for such packaging production is substantially simpler and therefore lower in cost than a mold for ABS, PC and other plastic injection, enabling the production of the mold itself to be of substantially lower cost, thus making it economical to produce different shaped molds for a relatively small quantity of devices.

Furthermore, according to the present invention, the lower temperatures required for such chemical reactions when compared to plastic molding, as well as the difference in the processed materials enables, in the same mold and as a single process, the production of monolithic package shells with a blend of colors, hues, opacity, and or other visual characteristics. Furthermore, due to the low temperature of the chemical reaction, additional objects such as metal labels or plastic figures can be inserted as floating objects inside the blend as part of the molding process of the device. Furthermore, different aromatic shells may be manufactured. The result of this process is a certain degree of difference between particular devices, creating a personalized end-product that is consumer appealing. Furthermore, other physical qualities of the resulting shell may be controlled, such as hardness, flexibility, impact resistance, and more.

### BRIEF DESCRIPTION OF THE DRAWINGS

The foregoing and other objects, aspects and advantages will be better understood from the following description of an embodiment of the invention with reference to the drawings, wherein:

FIG. 1A is a front view of a schematic block diagram of an exemplary embodiment of a pocketable consumer electronic device that is packaged in an elastomeric shell;

FIG. FIG. 1B is a side view of a schematic block diagram of an exemplary embodiment of a pocketable consumer electronic device that is packaged in an elastomeric shell;

FIG. 2A is a front view of a schematic block diagram of an exemplary embodiment of a pocketable consumer electronic device having a screen and pushbuttons that is packaged in an elastomeric shell;

FIG. 2B is a side view of a schematic block diagram of an exemplary embodiment of a pocketable consumer electronic device having a screen and pushbuttons that is packaged in an elastomeric shell;

FIG. 3 is a schematic block diagram of an exemplary embodiment of a mold for encapsulating a pocketable consumer electronic device in an elastomeric shell;

FIG. 4 is a flowchart of an exemplary process of packaging the exemplary embodiment of a pocketable consumer electronic device of FIG. 1 in an elastomeric shell.

### DETAILED DESCRIPTION OF THE INVENTION

The above-mentioned disadvantages and problems of consumer electronic package shells are addressed by the present invention, which will be understood by reading the following specification, which describes the use of elastomeric materials as a packaging shell for pocketable consumer electronic devices and the process of producing a device with the same.

In the following description of exemplary embodiments of the invention, reference is made to the drawings that illustrate specific exemplary embodiments in which the invention may be practiced. Those skilled in the art will appreciate that other embodiments may be utilized without departing from the spirit of the present invention; therefore the following detailed description of the invention should not be taken in a limiting sense. In various embodiments, there may be none, one, or more than one of the following described parts. Further, the parts can be modified and/or rearranged; generally, components or subcomponents may be combined with other components or subcomponents for higher integration and perhaps lower cost.

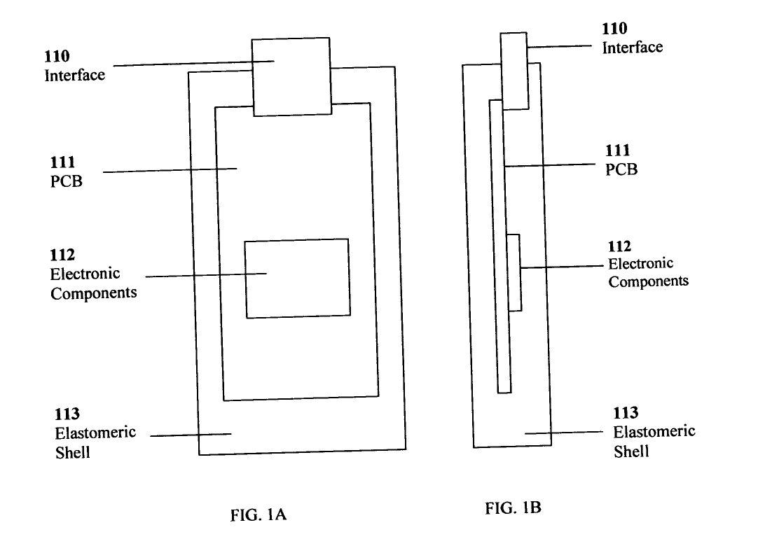

FIG. 1A and FIG. 1B are schematic block diagrams of an exemplary embodiment of a pocketable consumer electronic device that is packaged in an elastomeric shell. The device is comprised of one or more PCB 111 circuit boards, one or more Interfaces 110, one or more Electronic Components 112 and an Elastomeric Shell 113. The Interface 110 may be one or more of any of several types of interfaces, for example PCI, ISA, Universal Serial Bus (USB), FireWire, IDE, SCSI, RS-232 or other serial interface, parallel interface, Smart Media, Compact Flash (CF) interface, Sony Memory Stick interface, Multimedia Card (MMC), secure digital (SD), mini Secure Digital, Extreme digital (xD), Bluetooth, WiFi, ultrawideband, Infiniband, mobile phone interface, PDA interface and/or any other type of interface that may be utilized with a pocketable consumer electronic device. The Electronic Components 112 is a collection of electronic components that work together to provide the required functionality for the device. The Electronic Components 112 may be mounted on one or more sides of the PCB 111. In the depicted exemplary embodiment, the pocketable consumer electronic device is a USB flash storage device, the Interface 110 is a USB connector and the Electronic Components 112 is composed of at least a USB controller and a flash storage component and possibly additional components, for example memory components, CPUs, LEDs (Light Emitting Diodes), pushbuttons, displays, battery houses, resistors and capacitors or the like. In this exemplary embodiment the Elastomeric Shell 113 encapsulates the PCB 111, the Electronic Components 112 and partially encapsulates the Interface 110, which in this exemplary embodiment is a USB connector, in a way that physically isolates and seals the above components from external contact such as mechanical contact, air, water, dust particles and the like.

In some embodiments, the Elastomeric Shell 113 fully encapsulates the Interface 110, the invention is not so limited.

In some embodiments, the Elastomeric Shell 113 only partially encapsulates the PCB 111 and/or Electronic Components 112, the invention is not so limited. This enables further assembly of parts such as a screen, pushbuttons and the like, and access to device electronics such as LEDs and batteries fro replacement.

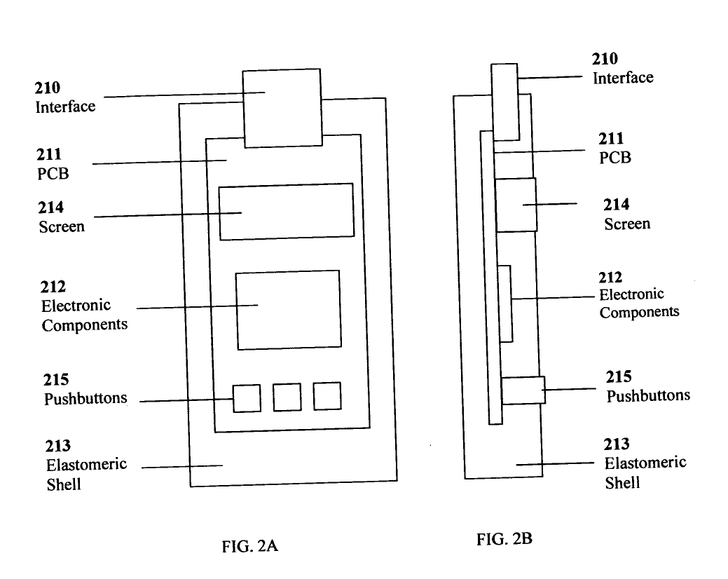

FIG. 2A and FIG. 2B are schematic block diagrams of an exemplary embodiment of a pocketable consumer electronic device having a screen and pushbuttons that is packaged in an elastomeric shell. In the depicted exemplary embodiment, the pocketable consumer electronic device is a mobile handset. The device is comprised of one or more PCB 211 circuit boards, one or more Interfaces 210, one or more Electronic Components 212, one or more Screen 214, one or more Pushbutton 215, and an Elastomeric Shell 213. The Electronic Components 212, Screen 214, and Pushbutton 215 are a collection of components that work together to provide the required functionality for the device. In some embodiments, Electronic Components 212 includes a battery casing. The Interface 210 is used to recharge a built in battery. In this exemplary embodiment the Elastomeric Shell 213 encapsulates the Electronic Components 212, only partially encapsulates PCB 211 and only partially encapsulates the Interface 210, in a way that physically isolates and seals the encapsulated components from external contact such as mechanical contact, air, water, dust particles and the like. The parts of PCB 211 that are not encapsulated are those where Screen 214 and Pushbuttons 215 are located.

In some embodiments, where a pocketable consumer electronic device comprises of one or more pushbuttons and/or one or more screens, the pushbuttons and/or screens or some of the pushbuttons and/or screens may be encapsulated within the elastomeric substance.

In some embodiments other components may be chosen not to be encapsulated. Generally, none, some, or all of the components comprising the consumer electronic device may be encapsulated using the method of the present invention, the invention is not so limited

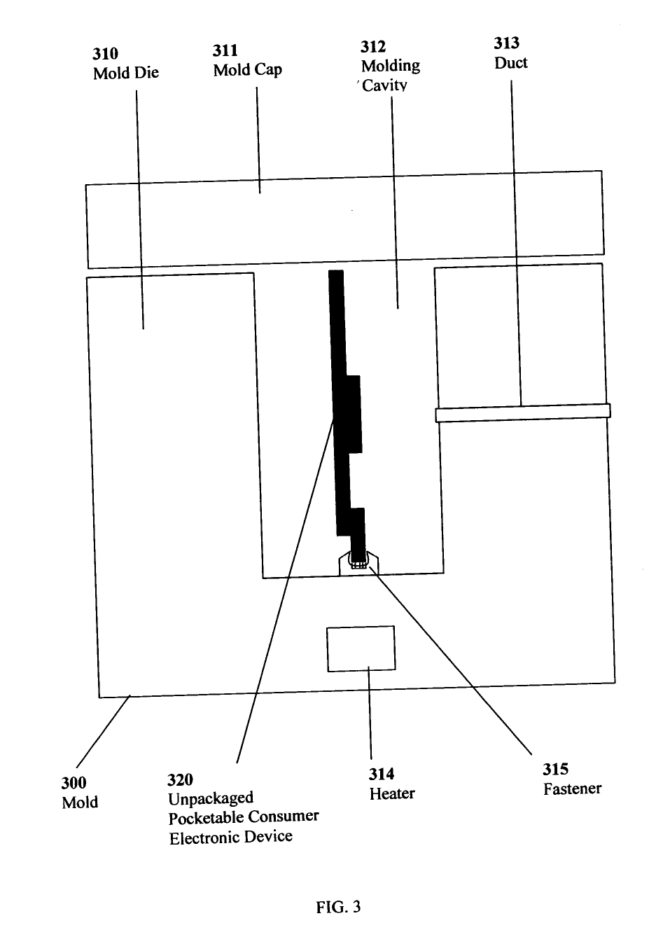

FIG. 3 is a schematic block diagram of an exemplary embodiment of a mold 300 for encapsulating a pocketable consumer electronic device in an elastomeric shell. The mold comprises of a Mold Die 310, a Mold Cap 311, a Duct 313, a Heater 314, and a Fastener 315. There may be one or a plurality of Mold Die 310. There may be none, one, or more Mold Cap 311. There may be none, one, or more Duct 313. There may be none, one, or more Heater 314. There may be none, one, or more Fastener 315. Generally, components or subcomponents of the mold 300 may be combined with other components or subcomponents of the mold 300. The Mold Die 310 may be formed out of a single or a plurality of parts, this invention is not so limited.

According to some embodiments, Mold Die 310 has one or more bucket-like Molding Cavity 312 where the chemical reaction occurs. The Molding Cavity 312 is designed to be large enough to at least partially accommodate the Unpackaged Consumer Electronic Device 320 and other product components that are to be encapsulated by the elastomeric shell. According to some embodiments, the Molding Cavity 312 may have further depressions, grooves, and other orifices in order to accommodate the physical shape of the Unpackaged Consumer Electronic Device 320.

The optional Mold Cap 311 covers the Mold Die 310. According to some embodiments, this creates a hermetically sealed mold.

The Mold Die 310 optionally includes one or more Duct 313. Duct 313 may be used for injecting molding material into Molding Cavity 312. Duct 313 may be used for ventilation of air and other gasses from the Molding Cavity 312. Duct 313 may be used for removal of excess molding material from Molding Cavity 312. According to some embodiments, one duct may be used for pumping out air and creating a vacuum inside Molding Cavity 312, and another duct may be used for injection of the chemical culture into the Molding Cavity 312. The Duct 313 may be located in the Mold Die 310 or in the Mold Cap 311 or in any other appropriate location, the invention is not so limited.

The optional Heater 314 provides means to control the temperature in the Molding Cavity 312 as required by the production process.

The Mold Die 310 optionally includes one or more Fastener 315 that physically supports the Unpackaged Consumer Electronic Device 320 while immersed in the molding culture in the Molding Cavity 312. This assures the exact location of the device electronics inside the final mold. The Fastener 315 may be located on the Mold Die 310 or on the Mold Cap 311 or in any other appropriate location, the invention is not so limited.

According to some embodiments, one or more Fastener 315 may mask parts of Unpackaged Consumer Electronic Device 320 from the molding culture thus enabling the masked parts of the device further assembly at a later time. Examples of areas that may be masked are areas on a device PCB where screen and pushbuttons will be attached, a battery replacement lid, and the like.

According to some embodiments, Fastener 315 may optionally have electrical connectivity, thus providing electronic access to the Unpackaged Consumer Electronic Device 320 and enabling operation of the device while in the mold, for functions such as testing, measurements, quality control and the like.

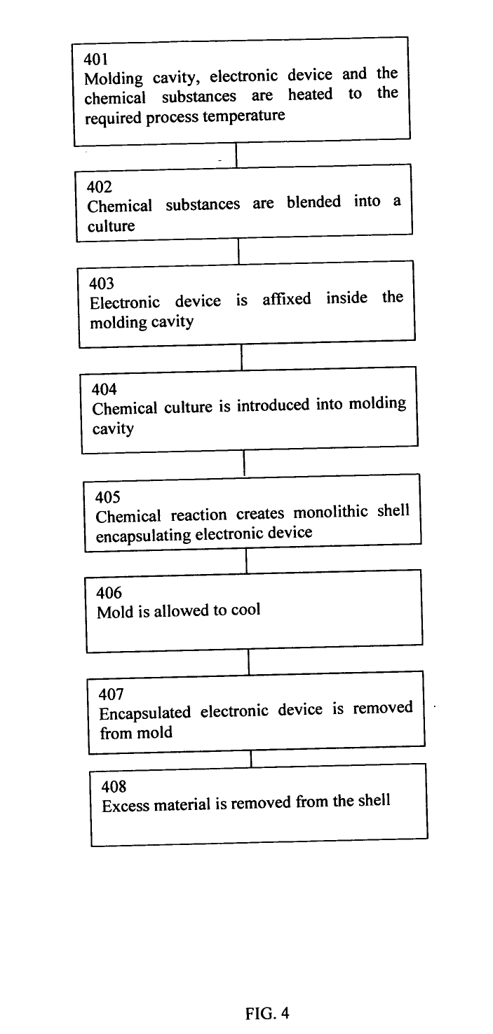

FIG. 4 is a flow chart describing an exemplary sequence of operations carried out in order to encapsulate device electronics in an elastomeric package shell using the mold described in FIG. 3.

In step 401 Molding Cavity 312, Unpackaged Consumer Electronic Device 320, selected chemical substances and possibly other components are heated to a temperature required by the molding process, depending on the chemical substances being used. In many cases this temperature varies between 50 to 100 degrees centigrade, but other temperatures may apply, the invention is not so limited. By preheating all the above components, no differences in temperature and humidity are enabled when the components are initially introduced, thus allowing for a more controlled end result of the chemical reaction. Examples of problems that may occur from heat and humidity differences are discoloration, air bubbles, and the like.

According to some embodiments none, some, or all of the aforementioned components are heated, the invention is not so limited.

In step 402 the chemical substances are blended into a culture to initiate a bonding chemical reaction. A single or a plurality of blended substances may be used. According to some embodiments, the chemical substances are blended outside the Mold Die 310. According to other embodiments, the chemical substances are blended in the Molding Cavity 312.

In step 403 Unpackaged Consumer Electronic Device 320 is positioned inside the Molding Cavity 312. According to some embodiments, one or more Fastener 315 is used to affix Unpackaged Consumer Electronic Device 320 into the exactly required position.

In step 404 the culture is introduced into Molding Cavity 312. The culture may be injected into Molding Cavity 312 or transferred into Molding Cavity 312 by some other technique; the invention is not so limited.

According to some embodiments, the culture is introduced into the Molding Cavity 312 before Unpackaged Consumer Electronic Device 320 is positioned; the invention is not so limited.

In step 405 the culture chemically reacts inside Molding Cavity 312, bonding and creating a monolithic mold that envelopes the Unpackaged Consumer Electronic Device 320.

In step 406 the Mold Die 310 and its contents are allowed to cool. According to some embodiments, Mold Cap 310 is removed in order to accelerate the cooling process. According to some embodiments, this may take several seconds to several minutes; the invention is not so limited. According to some embodiments an additional cooling system may be employed to accelerate the cooling process.

In step 407 the Mold Die 310 is opened by removing the Mold Cap 311 and the encapsulated consumer electronic device is extracted.

In step 408 any existing excess packaging shell material formed at the seams of Mold Die 310 and Mold Cap 311 is removed from the encapsulated consumer electronic device.

According to some embodiments, further manufacturing steps may occur at this point. For example, for a mobile handset as depicted in FIG. 2, the screen and pushbuttons may now be assembled in the voids not encapsulated by the shell.

While this invention has been described in detail with reference to exemplary embodiments thereof, it will be apparent to one skilled in the art that various changes can be made, and equivalents employed, without departing from the spirit of the invention.

We claim:

1. A method of encapsulating an electronic device comprising the steps of:
providing a molding die having a molding cavity;
providing an electronic device comprising electronic components and an electrical interface;
affixing the electronic device in the molding cavity of said molding die;
introducing a culture of molding materials into said molding cavity, wherein a chemical reaction causes a bonding of the culture encapsulating said electronic device,
wherein a monolithic shell that is environmentally durable is formed in the presence of said electronic device, bonded to said electronic device, and encapsulating said electronic device.

2. The method of claim 1, wherein said chemical reaction is carried out at a temperature no more than about 130 degrees Centigrade, under a pressure no more than about 2 atmospheres, and in no more than about 60 seconds.

3. The method of claim 1, wherein said molding die comprises a molding cap, wherein said molding cap is used to seal said molding die.

4. The method of claim 1, wherein said electronic device is at least a USB storage device.

5. The method of claim 1, wherein said electronic device has at least an internal power source.

6. The method of claim 1, wherein said electronic device is at least a mobile handset.

7. The method of claim 1, wherein said electronic device is at least a personal digital assistant.

8. The method of claim 1, wherein said electronic device is at least a digital camera.

9. The method of claim 1, wherein said electronic device is at least an audio playback device.

10. The method of claim 1 wherein said electronic device has at least a user interface component.

11. The method of claim 10, wherein user interface component is at least a light emitting diode.

12. The method of claim 10, wherein user interface component is at least a display.

13. The method of claim 10, wherein user interface component is at least a user input terminal.

14. The method of claim 1, wherein said electrical interface is USB connector.

15. The method of claim 1, wherein
said molding die further comprises a fastener with electrical contacts, wherein step said affixing the electronic device in the molding cavity of said molding die further comprises attaching said fastener to the electrical interface of said electronic device, wherein, electrical mating to the said electronic device is achieved,
wherein operation of said electronic device while in said mold die is enabled.

16. The method of claim 15, wherein said electrical mating is employed for at least the function of testing said electronic device.

17. The method of claim 1, wherein said electrical interface is a wireless interface.

18. The method of claim 1, wherein said culture of molding materials includes at least a polymerizable monomer.

19. The method of claim 1, wherein said chemical reaction results in at least an elastomeric polyurethane shell.

20. The method of claim 1, wherein said molding die, said culture of molding material, and said electronic device are preheated to a desired temperature before step said introducing culture of molding materials into said molding cavity.

21. The method of claim 1, wherein said culture of molding material further includes personalization elements.

22. A method of encapsulating an electronic device comprising the steps of:
providing a molding die having a molding cavity;
providing an electronic device comprising electronic components and an electrical interface;
introducing a culture of molding materials into said molding cavity;
affixing the electronic device in the molding cavity of said molding die, wherein a chemical reaction causes a bonding of the culture encapsulating said electronic device,
wherein a monolithic shell that is environmentally durable is formed in the presence of said electronic device, bonded to said electronic device, and encapsulating said electronic device.

23. The method of claim 1, further comprising
cooling said molding die and its contents;
extracting the resulting packaged electronic device from molding die; and
removing excess material from the shell.
